(19) United States
(12) Patent Application Publication
(10) Pub. No.: US 2024/0324467 A1
(43) Pub. Date: Sep. 26, 2024

(54) MAGNETOSTRICTIVE TORQUE SENSOR

(71) Applicant: Proterial, Ltd., Tokyo (JP)

(72) Inventors: Akitoshi FUJIMORI, Tokyo (JP); Takashi ONIMOTO, Tokyo (JP)

(73) Assignee: Proterial, Ltd., Tokyo (JP)

(21) Appl. No.: 18/610,559

(22) Filed: Mar. 20, 2024

(30) Foreign Application Priority Data
Mar. 24, 2023 (JP) 2023-047965

(51) Int. Cl. H10N 35/00; H10N 35/80

(52) U.S. Cl. CPC H10N 35/101; H10N 35/80

(57) ABSTRACT

A magnetostrictive torque sensor that is configured to be attached around a rotating shaft exhibiting a magnetostrictive effect and detects torque transmitted by the rotating shaft. The magnetostrictive torque sensor is provided with a holder being composed of a resin and including a cylinder portion with a hollow cavity in the center through which the rotating shaft is inserted, and a flexible substrate that includes a detection portion on which a coil group including a combination of a plurality of detection coils aligned in a predetermined direction is formed by a wiring pattern, and a signal line portion on which a plurality of signal lines electrically connecting the coil group to an external device are formed by a wiring pattern. The flexible substrate is arranged in such a manner that the detection portion is wrapped around an outer circumference of the cylinder portion of the holder and held by the holder, and a portion of the signal line portion is led out of the holder.

### CROSS-REFERENCE TO RELATED APPLICATIONS

The present application is based on Japanese patent application No. 2023-047965 filed on Mar. 24, 2023, the entire contents of which are incorporated herein by reference.

### TECHNICAL FIELD

The present invention relates to a magnetostrictive torque sensor to detect torque transmitted by a rotating shaft exhibiting a magnetostrictive effect.

### BACKGROUND OF THE INVENTION

Conventionally, magnetostrictive torque sensors are used to detect torque of, e.g., an output rotating shaft of an automobile engine, etc. Magnetostrictive torque sensors are configured to detect torque applied to a rotating shaft based on changes in the inductance of a detection coil placed around the rotating shaft, using the magnetostrictive effect in which the magnetic permeability of the rotating shaft changes due to stress. The present applicant has proposed a magnetostrictive torque sensor that has a flexible substrate having plural detection coils formed thereon and placed around a rotating shaft and detects torque applied to the rotating shaft based on changes in the inductances of the plural detection coils (see Patent Literature 1).

In the magnetostrictive torque sensor described in Patent Literature 1, the flexible substrate having plural detection coils is housed in a resin housing. Plural terminals are provided at an end of the flexible substrate, and signal lines of a cable are connected to these terminals inside the resin housing. The cable is led out of the resin housing and is connected to a control device.
Citation List Patent Literature 1: JP2022-74405A

### SUMMARY OF THE INVENTION

It is sometimes difficult to secure installation spaces of torque sensors around rotating shafts, and there is a demand for reducing the size of torque sensors. The invention was made in response to this demand, and it is an object of the invention to provide a magnetostrictive torque sensor that can be reduced in size.

To achieve the object described above, the invention provides a magnetostrictive torque sensor that is configured to be attached around a rotating shaft exhibiting a magnetostrictive effect and detects torque transmitted by the rotating shaft, the magnetostrictive torque sensor comprising:
a holder being composed of a resin and comprising a cylinder portion with a hollow cavity in a center through which the rotating shaft is inserted; and
a flexible substrate that comprises a detection portion on which a coil group comprising a combination of a plurality of detection coils aligned in a predetermined direction is formed by a wiring pattern, and a signal line portion on which a plurality of signal lines electrically connecting the coil group to an external device are formed by a wiring pattern,
wherein the flexible substrate is arranged in such a manner that the detection portion is wrapped around an outer circumference of the cylinder portion of the holder and held by the holder, and a portion of the signal line portion is led out of the holder.

### Advantageous Effects of the Invention

According to the invention, it is possible to reduce the size of the magnetostrictive torque sensor, allowing for installation space saving.

### BRIEF DESCRIPTION OF DRAWINGS

FIG. 1 is a perspective view showing a magnetostrictive torque sensor in an embodiment of the present invention, which is shown together with a rotating shaft to be subjected to detection.

FIG. 2 is an exploded perspective view showing the magnetostrictive torque sensor.

FIG. 3 is an exploded perspective view showing the magnetostrictive torque sensor when viewed in a direction different from in FIG. 2.

FIG. 4 is a cross-sectional view showing the magnetostrictive torque sensor.

FIG. 5A is a plan view showing one flexible substrate.

FIG. 5B is a plan view showing a base material from which plural flexible substrates are cut out.

FIG. 6 is a cross-sectional view showing a layer structure of the flexible substrate.

FIGS. 7A to 7D are plan views showing first to fourth wiring layers.

FIG. 8 is a schematic circuit diagram illustrating a configuration example of an electric circuit composed of the flexible substrate, an oscillator and a voltmeter.

FIG. 9A is a configuration diagram illustrating a state in which a cover member and the flexible substrate are attached to a holder, as viewed in an axial direction.

FIG. 9B is a configuration diagram in which illustration of the cover member is omitted from the state shown in FIG. 9A.

FIG. 10A is a configuration diagram illustrating a recessed portion of the holder as viewed in the axial direction.

FIG. 10B is a perspective view showing a portion around the recessed portion.

FIGS. 11A and 11B are perspective views showing the cover member.

FIG. 12 is a configuration diagram illustrating the recessed portion of the holder and a raised portion of the cover member in the first modified example, which are shown together with a portion of a linear portion of the flexible substrate.

FIG. 13 is a configuration diagram illustrating the recessed portion of the holder and the raised portion of the cover member in the second modified example, which are shown together with a portion of the linear portion of the flexible substrate.

FIG. 14 is a configuration diagram illustrating the recessed portion of the holder and the raised portion of the cover member in the third modified example, which are shown together with a portion of the linear portion of the flexible substrate.

### DETAILED DESCRIPTION OF THE INVENTION

### Embodiment

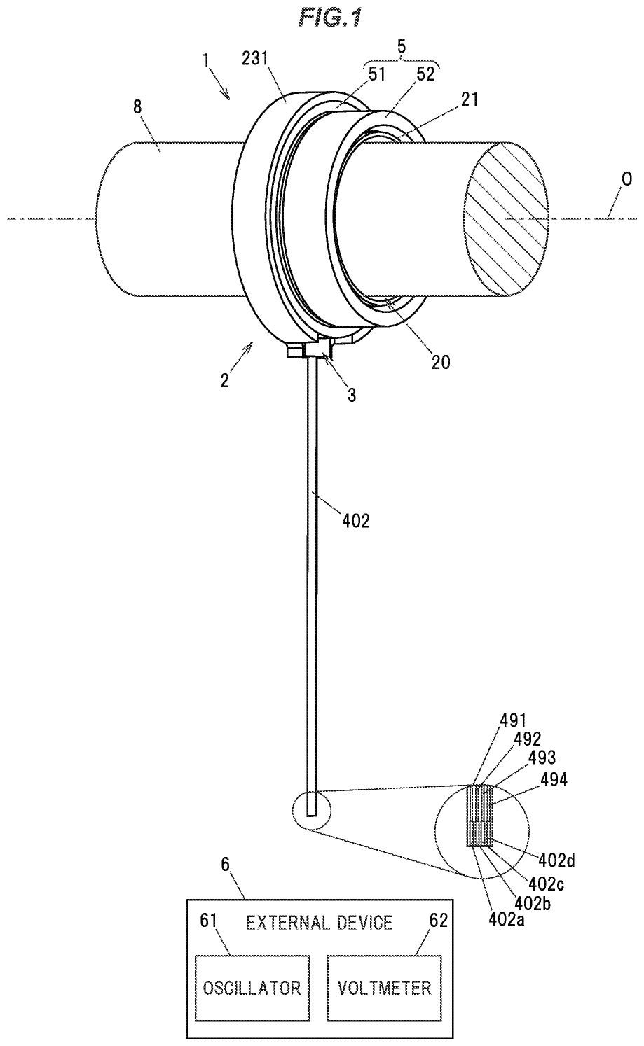

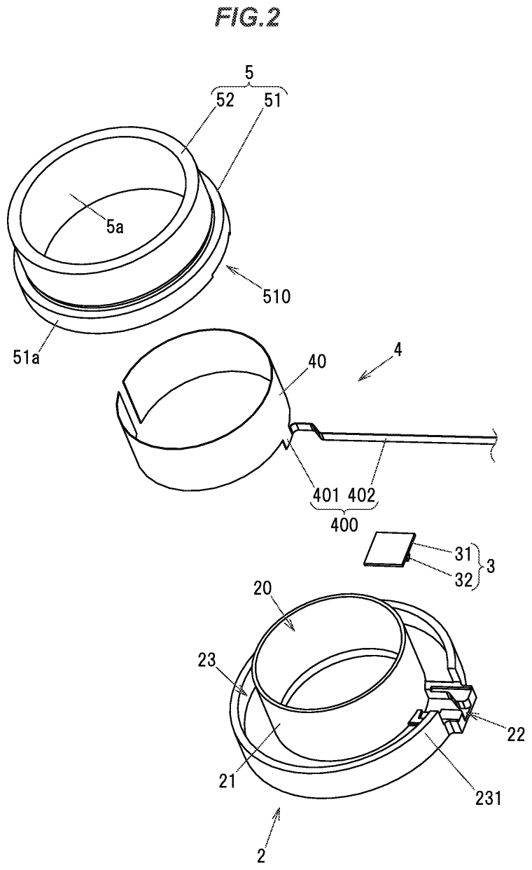

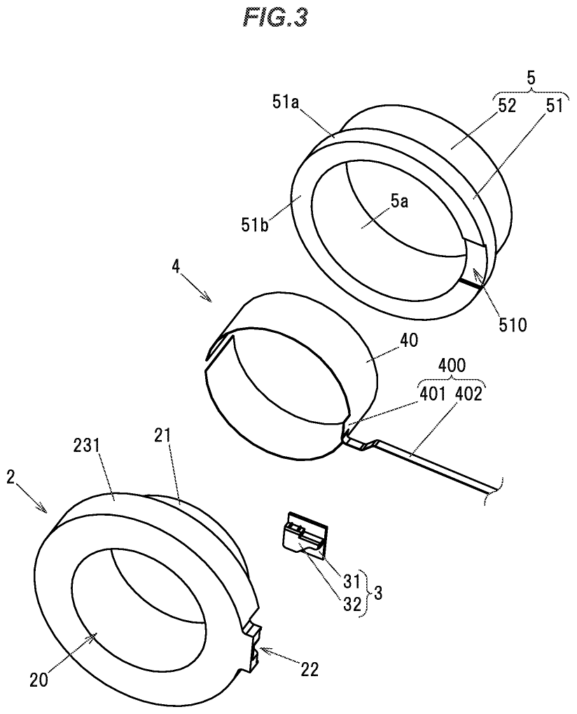

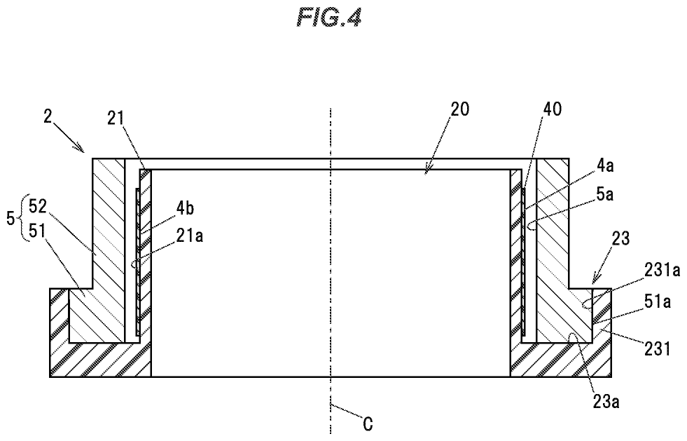

FIG. 1 is a perspective view showing a magnetostrictive torque sensor 1 in an embodiment of the invention, which is shown together with a rotating shaft 8 to be subjected to detection. FIG. 2 is an exploded perspective view showing the magnetostrictive torque sensor 1. FIG. 3 is an exploded perspective view showing the magnetostrictive torque sensor 1 when viewed in a direction different from in FIG. 2. FIG. 4 is a cross-sectional view showing the magnetostrictive torque sensor 1.

The magnetostrictive torque sensor 1 is attached around the rotating shaft 8 and detects torque transmitted by the rotating shaft 8. The rotating shaft 8 is, e.g., a shaft that transmits a driving force of a drive source such as an automobile engine or electric motor. The torque detection result obtained by the magnetostrictive torque sensor 1 is used to control the drive source or an automatic transmission, etc.

The rotating shaft 8 is a ferromagnetic material exhibiting a magnetostrictive effect, and rotates around a rotation axis O to transmit torque. Here, the magnetostrictive effect is a phenomenon in which the shape of a ferromagnetic material is distorted when the ferromagnetic material is magnetized by applying a magnetic field. By using this phenomenon in an opposite manner and detecting changes in magnetic properties caused by distortion of the shape, it is possible to detect torque applied to the rotating shaft 8. It is possible to suitably use the rotating shaft 8 obtained by, e.g., carburizing, quenching and tempering a shaft-shaped body made of chrome steel containing chrome, such as a chrome steel, a chrome-molybdenum steel or a nickel-chrome molybdenum steel, and further performing shot peening. Hereinafter, a direction parallel to the rotation axis O of the rotating shaft 8 will be referred to as an axial direction.

The magnetostrictive torque sensor 1 has a holder 2, a cover member 3, a flexible substrate 4, a magnetic ring 5 made of a soft magnetic material, and an external device 6 arranged outside the holder 2. The external device 6 has an oscillator 61 and a voltmeter 62 and is electrically connected to the flexible substrate 4. The operation of the external device 6 will be described later.

The holder 2 is made of, e.g., a resin material such as PPS (polyphenylene sulfide) and is injection molded. The holder 2 has the cylinder portion 21 with a hollow cavity 20 in the center through which the rotating shaft 8 is inserted, a recessed portion 22 to house a portion of the flexible substrate 4, and an annular groove 23 that houses one axial end of the magnetic ring 5. A central axis C of the cylinder portion 21 coincides with the rotation axis O of the rotating shaft 8. The recessed portion 22 is provided on the outer side of the cylinder portion 21. The annular groove 23 is provided around an outer circumference of the cylinder portion 21 except for the portion where the recessed portion 22 is formed. Both the recessed portion 22 and the annular groove 23 are open on one side in the axial direction.

The cover member 3 is made of, e.g., the same resin material as the holder 2 and integrally has a plate portion 31 covering the one side of the recessed portion 22 in the axial direction, and a raised portion 32 fitted into the recessed portion 22. The details of the shapes of the cover member 3 and the recessed portion 22 will be described later.

The magnetic ring 5 is made of, e.g., steel or a sintered magnetic material, has soft magnetic properties, and is formed in a cylindrical shape with an inner diameter larger than an outer diameter of the cylinder portion 21 of the holder 2. When the magnetic ring 5 is made of steel, a magnetic steel material such as electromagnetic stainless steel can be suitably used and, e.g., deep drawing can be used as the forming method. Alternatively, the magnetic ring 5 may be formed by cutting a long pipe-shaped steel material to a predetermined length. The magnetic ring 5 is fixed to the holder 2 by, e.g., adhesive bonding. The magnetic ring 5 is aligned with the cover member 3 in the axial direction and restricts movement of the cover member 3 in a direction in which the raised portion 32 separates away from the recessed portion 22 of the holder 2.

In the present embodiment, the magnetic ring 5 integrally has a large diameter portion 51 and a small diameter portion 52 which have different outer diameters. An inner diameter of the large diameter portion 51 and an inner diameter of the small diameter portion 52 are the same. The large diameter portion 51 is provided at the one axial end of the magnetic ring 5 and is housed in the annular groove 23 of the holder 2. By fitting the large diameter portion 51 into the annular groove 23 in a spigot and socket manner, the magnetic ring 5 is positioned relative to the holder 2. In more particular, by contact of an outer circumferential surface 51a of the large diameter portion 51 with an inner circumferential surface 231a of an annular wall 231 forming an outer circumference of the annular groove 23, the magnetic ring 5 is positioned relative to the holder 2 in the radial direction perpendicular to the axial direction.

As shown in FIG. 3, on an axial end surface 51b of the large diameter portion 51 of the magnetic ring 5, a notch 510 recessed from the end surface 51b in the axial direction is formed on a portion facing the plate portion 31 of the cover member 3. When the cover member 3 and the magnetic ring 5 are assembled to the holder 2, a portion of the plate portion 31 of the cover member 3 is housed in the notch 510 and the end surface 51b of the large diameter portion 51 is in contact with a bottom surface 23a of the annular groove 23.

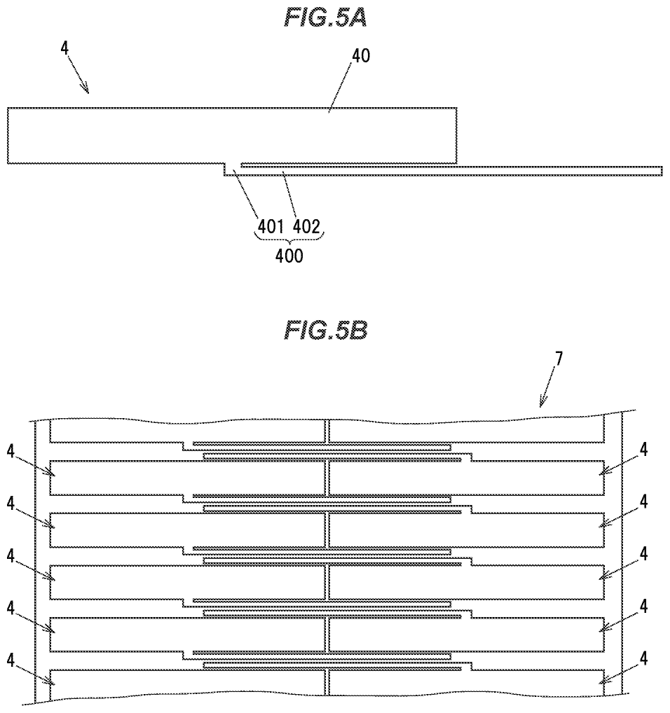

FIG. 5A is a plan view showing one flexible substrate 4. FIG. 5B is a plan view showing a base material 7 from which plural flexible substrates 4 are cut out. The flexible substrate 4 is manufactured by cutting the base material 7.

The flexible substrate 4 integrally has a detection portion 40 having plural detection coils to detect a magnetic field of the rotating shaft 8, and a signal line portion 400 on which plural signal lines electrically connecting the external device 6 to the detection portion 40 are formed by a wiring pattern. The plural detection coils and the plural signal lines are not shown in FIGS. 5A and 5B. The flexible substrate 4 is arranged in such a manner that the detection portion 40 is wrapped around the outer circumference of the cylinder portion 21 of the holder 2 and held by the holder 2, and a portion of the signal line portion 400 is led out of the holder 2. On the detection portion 40, coil groups each composed of a combination of the plural detection coils aligned in a predetermined direction are formed by wiring patterns. The detection portion 40 has a rectangular shape with a long-side direction coincident with an alignment direction of the plural detection coils.

The signal line portion 400 has a protruding portion 401 protruding from the detection portion 40 in a direction perpendicular to the long-side direction, and a linear portion 402 extending from the protruding portion 401 in the long-side direction. This shape of the flexible substrate 4 allows plural flexible substrates 4 to be cut out of the base material 7 with a reduced wasted area as shown in FIG. 5B, which can improve the yield. A length of the linear portion 402 is, e.g., 50 mm or more and 100 mm or less.

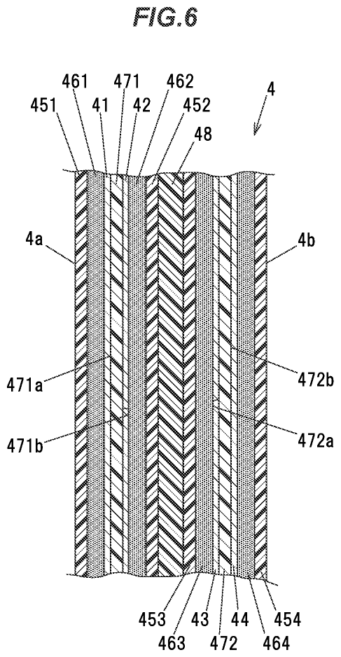

A portion of the linear portion 402 including a tip portion and excluding a base end portion near the protruding portion 401 is led out of the holder 2. First to fourth electrodes 402a to 402d are formed at the tip portion of the linear portion 402, as shown enlarged in FIG. 1. The linear portion 402 of the flexible substrate 4 may be directly connected to the external device 6, or may be connected to the external device 6 through a cable having plural electric wires. Next, an example configuration of the detection portion 40 will be described in detail with reference to FIGS. 6 to 8.

FIG. 6 is a cross-sectional view showing a layer structure of the flexible substrate 4. The flexible substrate 4 has a multilayer structure which has first to fourth wiring layers 41 to 44 and in which a coverlay film 451, an adhesive layer 461, the first wiring layer 41, a first base film 471, the second wiring layer 42, an adhesive layer 462, a coverlay film 452, a double-sided tape 48, a coverlay film 453, an adhesive layer 463, the third wiring layer 43, a second base film 472, the fourth wiring layer 44, an adhesive layer 464 and a coverlay film 454 are stacked in this order from one surface 4a, which is located on the outer side of the curve when wrapped around the outer circumference of the cylinder portion 21, to the other surface 4b on the inner side of the curve.

The first wiring layer 41 and the second wiring layer 42 are wiring patterns formed by etching copper foil and are respectively formed on a front surface 471a and a back surface 471b of the first base film 471. Likewise, the third wiring layer 43 and the fourth wiring layer 44 are wiring patterns formed by etching copper foil and are respectively formed on a front surface 472a and a back surface 472b of the second base film 472. The coverlay films 451, 452, 453, 454 are protective films adhered to the first to fourth wiring layers 41 to 44 by the adhesive layers 461, 462, 463, 464. The first and second base films 471, 472 and the coverlay films 451, 452, 453, 454 are made of an insulating resin such as polyimide.

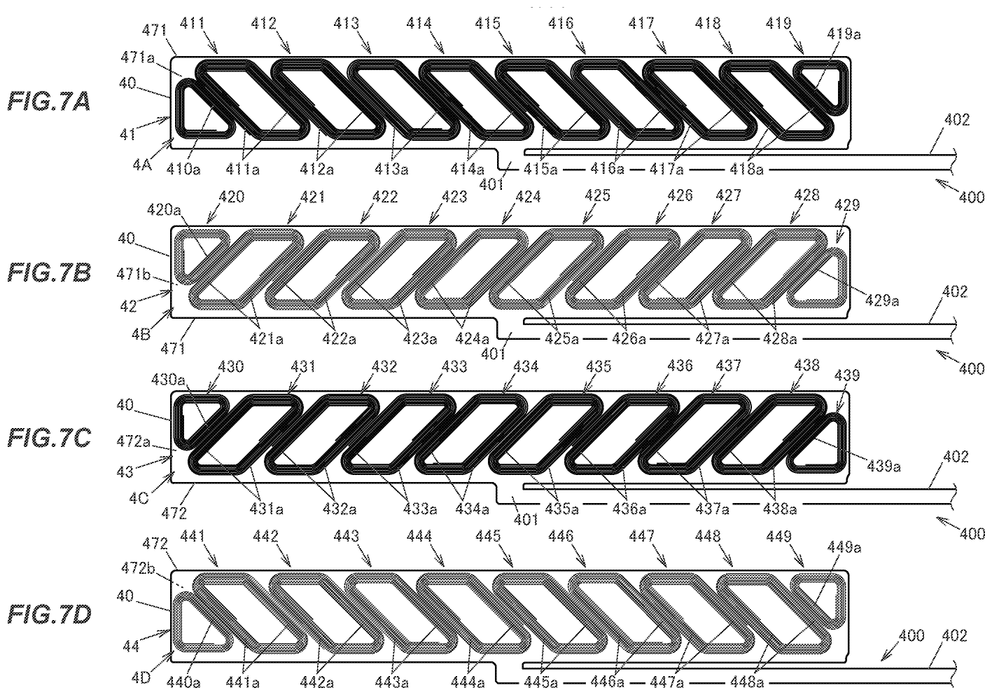

FIG. 7A is a plan view showing a wiring pattern of the first wiring layer 41 formed on the front surface 471a of the first base film 471. FIG. 7B is a plan view showing a wiring pattern of the second wiring layer 42 when viewed from the front surface 471a side of the first base film 471. FIG. 7C is a plan view showing a wiring pattern of the third wiring layer 43 formed on the front surface 472a of the second base film 472. FIG. 7D is a plan view showing a wiring pattern of the fourth wiring layer 44 when viewed from the front surface 472a side of the second base film 472.

On the first wiring layer 41, first to tenth detection coils 410 to 419 aligned in the long-side direction of the detection portion 40 are formed by a wiring pattern. The first and tenth detection coils 410 and 419 have a triangular shape, and the second to ninth detection coils 411 to 418 have a parallelogram shape. Likewise, on the second wiring layer 42, first to tenth detection coils 420 to 429 aligned in the long-side direction of the detection portion 40 are formed by a wiring pattern. The first and tenth detection coils 420 and 429 have a triangular shape, and the second to ninth detection coils 421 to 428 have a parallelogram shape.

On the third wiring layer 43, first to tenth detection coils 430 to 439 aligned in the long-side direction of the detection portion 40 are formed by a wiring pattern. The first and tenth detection coils 430 and 439 have a triangular shape, and the second to ninth detection coils 431 to 438 have a parallelogram shape. Likewise, on the fourth wiring layer 44, first to tenth detection coils 440 to 449 aligned in the long-side direction of the detection portion 40 are formed by a wiring pattern. The first and tenth detection coils 440 and 449 have a triangular shape, and the second to ninth detection coils 441 to 448 have a parallelogram shape.

The first to tenth detection coils 410 to 419 of the first wiring layer 41 and the first to tenth detection coils 440 to 449 of the fourth wiring layer 44 respectively have straight portions 410a to 419a and 440a to 449a which are inclined toward one side at a predetermined angle (+45°) relative to a short-side direction of the detection portion 40. The first to tenth detection coils 420 to 429 of the second wiring layer 42 and the first to tenth detection coils 430 to 439 of the third wiring layer 43 have respectively straight portions 420a to 429a and 430a to 439a which are inclined toward the other side at the predetermined angle (−45°) relative to the short-side direction of the detection portion 40.

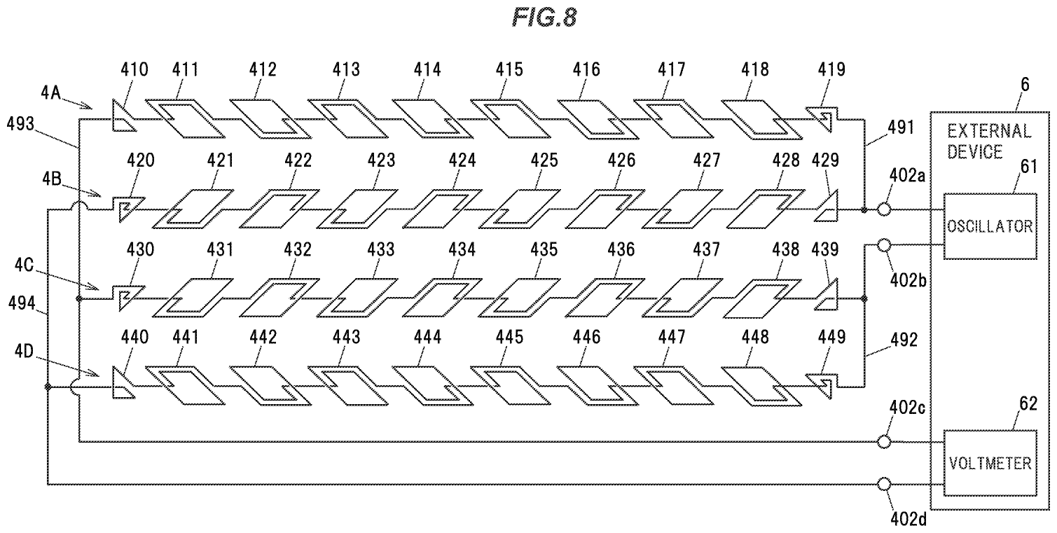

FIG. 8 is a schematic circuit diagram illustrating a configuration example of an electric circuit composed of the flexible substrate 4, the oscillator 61 and the voltmeter 62. The first to tenth detection coils 410 to 419 of the first wiring layer 41 are connected in series to form a first coil group 4A, and the first to tenth detection coils 420 to 429 of the second wiring layer 42 are connected in series to form a second coil group 4B. Likewise, the first to tenth detection coils 430 to 439 of the third wiring layer 43 are connected in series to form a third coil group 4C, and the first to tenth detection coils 440 to 449 of the fourth wiring layer 44 are connected in series to form a fourth coil group 4D.

The first coil group 4A and the third coil group 4C, and the second coil group 4B and the fourth coil group 4D, are connected respectively in series between the first electrode 402a and the second electrode 402b. One end of the first coil group 4A and one end of the second coil group 4B are connected to the first electrode 402a by a first signal line 491. One end of the third coil group 4C and one end of the fourth coil group 4D are connected to the second electrode 402b by a second signal line 492.

A third signal line 493, which connects the other end of the first coil group 4A and the other end of the third coil group 4C in series, is connected to the third electrode 402c. A fourth signal line 494, which connects the other end of the second coil group 4B and the other end of the fourth coil group 4D in series, is connected to the fourth electrode 402d. The first to fourth signal lines 491 to 494 are formed by a wiring pattern on the signal line portion 400. The oscillator 61 applies an AC voltage between the first electrode 402a and the second electrode 402b. The voltmeter 62 measures a voltage between the third electrode 402c and the fourth electrode 402d.

When torque is applied to the rotating shaft 8, magnetic permeability in the direction at +45 degrees from the axial direction decreases (or increases) and magnetic permeability in the direction at −45 degrees from the axial direction increases (or decreases). Therefore, when torque is applied to the rotating shaft 8 in a state in which AC voltage is applied from the oscillator 61, inductances of the first coil group 4A and the fourth coil group 4D decrease (or increase) and inductances of the second coil group 4B and the third coil group 4C increase (or decrease). Since this results in a change in the voltage measured by the voltmeter 62, the torque applied to the rotating shaft 8 can be detected based on this change in voltage.

Note that FIGS. 7A to 7D do not show wiring patterns of portions connecting in series between the first to tenth detection coils 410 to 419, 420 to 429, 430 to 439 and 440 to 449 of the first to fourth wiring layers 41 to 44, and wiring patterns constituting the first to fourth signal lines 491 to 494.

The other surface 4b of the detection portion 40 is adhered to an outer circumferential surface 21a of the cylinder portion 21 of the holder 2 with an adhesive. The magnetic ring 5 is arranged so as to surround an outer circumference of the detection portion 40. The magnetic ring 5 increases the magnetic flux linking with each of the detection coils 410 to 419, 420 to 429, 430 to 439 and 440 to 449, thereby increasing the sensitivity of the magnetostrictive torque sensor 1. A space is formed between the one surface 4a of the detection portion 40 and an inner circumferential surface 5a of the magnetic ring 5, so that the flexible substrate 4 and the magnetic ring 5 are not in contact with each other.

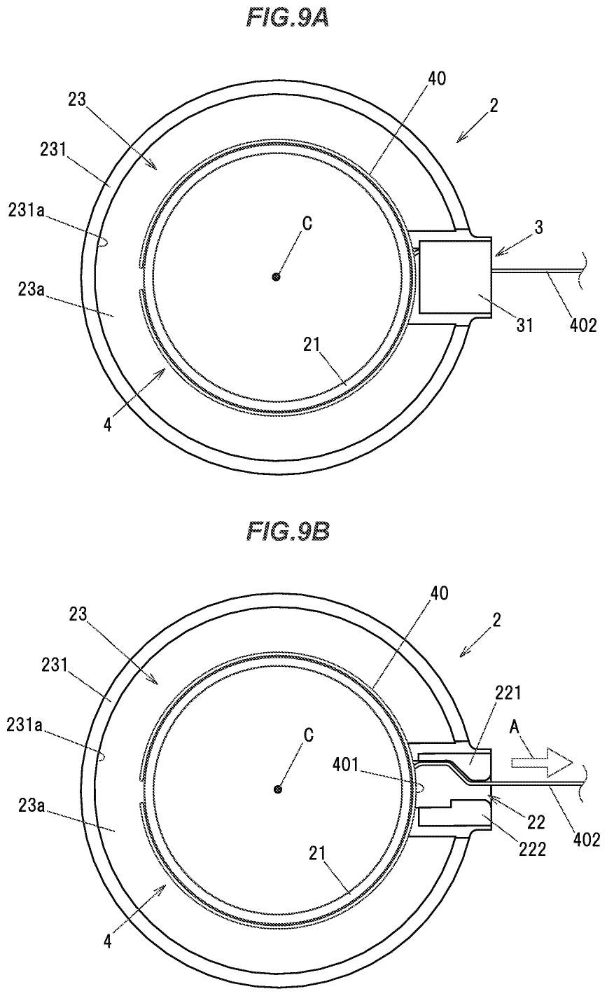

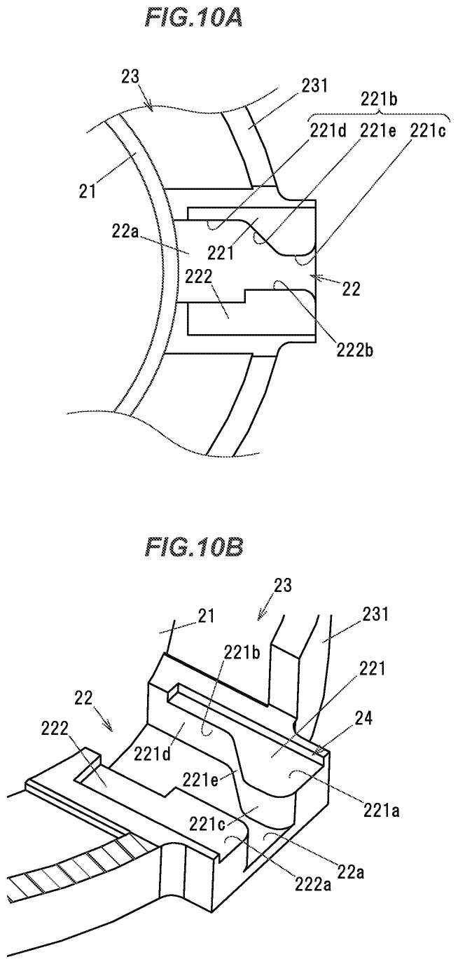

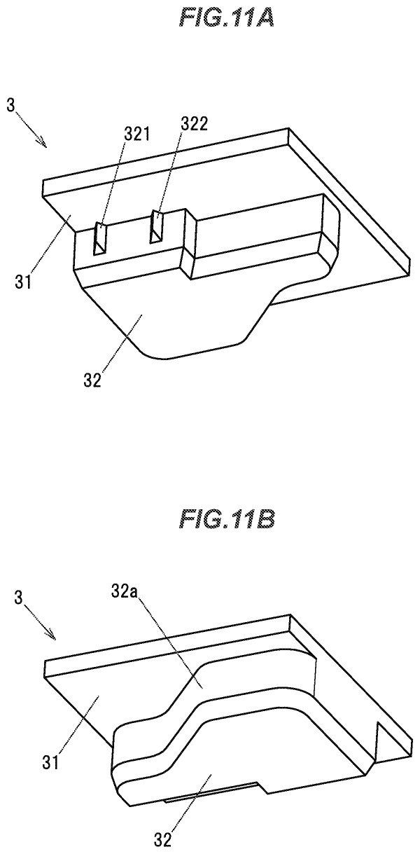

FIG. 9A is a configuration diagram illustrating a state in which the cover member 3 and the flexible substrate 4 are attached to the holder 2, as viewed in the axial direction. FIG. 9B is a configuration diagram in which illustration of the cover member 3 is omitted from the state shown in FIG. 9A. FIG. 10A is a configuration diagram illustrating the recessed portion 22 of the holder 2 as viewed in the axial direction. FIG. 10B is a perspective view showing a portion around the recessed portion 22. FIGS. 11A and 11B are perspective views showing the cover member 3 as viewed from different directions. FIG. 10B shows a state in which a portion of the annular wall 231 on the near side of the drawing relative to the recessed portion 22 is cut off.

The recessed portion 22 houses a portion of the linear portion 402 near the protruding portion 401. A plate portion housing portion 24 to house the plate portion 31 of the cover member 3 is formed on one side of the recessed portion 22 in the axial direction. The recessed portion 22 is formed between a first wall portion 221 and a second wall portion 222 of the holder 2. The first wall portion 221 and the second wall portion 222 are provided so as to protrude in the axial direction from a bottom surface 22a of the recessed portion 22. The plate portion 31 of the cover member 3 is in contact with a top surface 221a of the first wall portion 221 and a top surface 222a of the second wall portion 222. The linear portion 402 is bent inside the recessed portion 22 and is led out of the holder 2 so as to extend in the radial direction which is perpendicular to a circumferential direction of the cylinder portion 21.

The first wall portion 221 and the second wall portion 222 face each other with the recessed portion 22 in between. A facing surface 221b of the first wall portion 221, which is the surface facing the second wall portion 222, and a facing surface 222b of the second wall portion 222, which is the surface facing the first wall portion 221, are inner surfaces of the recessed portion 22. The linear portion 402 of the flexible substrate 4 is curved along the facing surface 221b of the first wall portion 221 and is sandwiched and held between the facing surface 221b of the first wall portion 221 and an outer peripheral surface 32a of the raised portion 32 of the cover member 3. The surfaces (the one surface 4a and the other surface 4b) of the linear portion 402 inside the recessed portion 22 are parallel to the central axis C of the cylinder portion 21, and the linear portion 402 is curved in the thickness direction thereof inside the recessed portion 22.

Curving the linear portion 402 in this manner prevents the lifting of a portion of the detection portion 40 from the cylinder portion 21 due to the restoring force of the curved linear portion 402. That is, if the linear portion 402 extends in a direction perpendicular to the long-side direction of the detection portion 40 and the linear portion 402 is curved near the detection portion 40, the detection portion 40 near the base of the linear portion 402 may be lifted from the cylinder portion 21 by the restoring force of the linear portion 402, causing a decrease in detection accuracy. However, in the present embodiment, such lifting can be suppressed since the signal line portion 400 extends from the protruding portion 401 along the long-side direction of the detection portion 40.

The facing surface 221b of the first wall portion 221 includes an exit-side guide surface 221c in contact with the linear portion 402 near an exit of the recessed portion 22 which is located on the outer circumferential end side of the holder 2, an entrance-side guide surface 221d in contact with the linear portion 402 near an entrance of the recessed portion 22 which is located near the cylinder portion 21, and an inclined guide surface 221e between the exit-side guide surface 221c and the entrance-side guide surface 221d. The linear portion 402 extends along the entrance-side guide surface 221d, the inclined guide surface 221e and the exit-side guide surface 221c inside the recessed portion 22.

The exit-side guide surface 221c is a flat surface along a direction perpendicular to the central axis C of the cylinder portion 21. The entrance-side guide surface 221d is a flat surface parallel to the exit-side guide surface 221c and is offset from the exit-side guide surface 221c in a direction away from the second wall portion 222. The inclined guide surface 221e is an inclined surface inclined with respect to a direction perpendicular to the central axis C of the cylinder portion 21 and forms an obtuse angle with the entrance-side guide surface 221d and the exit-side guide surface 221c.

The raised portion 32 of the cover member 3 has plural protrusions 321, 322 as shown in FIG. 11A that are pressed against the facing surface 222b of the second wall portion 222, the plural protrusions 321, 322 pressed against the facing surface 222b of the second wall portion 222 cause elastic deformation of the raised portion 32, and the raised portion 32 is pressed by its restoring force toward the first wall portion 221.

The linear portion 402 is sandwiched and held inside the recessed portion 22, hence, even if the linear portion 402 outside the holder 2 is pulled, reach of the pulling force to the detection portion 40 through the protruding portion 401 is suppressed and a decrease in detection accuracy of the magnetostrictive torque sensor 1 is suppressed. In addition, the linear portion 402 is led out of the holder 2 so as to extend in the radial direction perpendicular to the circumferential direction of the cylinder portion 21, hence, even if the linear portion 402 is pulled in the extending direction of the linear portion 402 indicated by the arrow A in FIG. 9B, generation of rotation moment in the holder 2 due to the pulling force is suppressed.

### Effects of the Embodiment

In the embodiment described above, the linear portion 402 of the flexible substrate 4 is led out of the holder 2, hence, connection of the flexible substrate 4 to the cable does not need to be inside the holder 2 and the magnetostrictive torque sensor 1 can thereby be reduced in size. Therefore, the magnetostrictive torque sensor 1 can be easily arranged even if the installation space around the rotating shaft 8 is narrow.

### Modified Examples

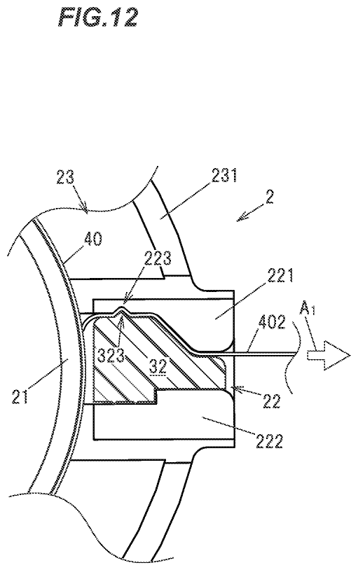

Next, the first to third modified examples of the shapes of the recessed portion 22 of the holder 2 and the raised portion 32 of the cover member 3 will be described with reference to FIGS. 12 to 14.

FIG. 12 is a configuration diagram illustrating the recessed portion 22 of the holder 2 and the raised portion 32 of the cover member 3 in the first modified example, which are shown together with a portion of the linear portion 402 of the flexible substrate 4. In FIG. 12, the direction in which the linear portion 402 is led out of the recessed portion 22 is indicated by the arrow A1. In the first modified example, a reentrant angle (concave angle) portion 223 is provided on the recessed portion 22, a salient angle (convex angle) portion 323 corresponding to the reentrant angle portion 223 is provided on the raised portion 32, and the linear portion 402 is arranged between the reentrant angle portion 223 and the salient angle portion 323. When the linear portion 402 is pulled in the direction of the arrow A1 outside the holder 2, the linear portion 402 is pressed against the salient angle portion 323 by the pulling force. As a result, the contact surface pressure between the salient angle portion 323 and the linear portion 402 increases, the pulling force is absorbed, and transmission of the pulling force to the protruding portion 401 side is suppressed. The reentrant angle portion 223 is recessed in a direction perpendicular to the direction of the arrow A1, and the salient angle portion 323 protrudes toward the reentrant angle portion 223 in the direction perpendicular to the direction of the arrow A1.

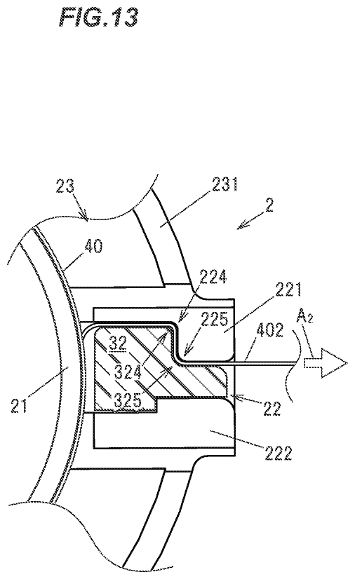

FIG. 13 is a configuration diagram illustrating the recessed portion 22 of the holder 2 and the raised portion 32 of the cover member 3 in the second modified example, which are shown together with a portion of the linear portion 402 of the flexible substrate 4. In FIG. 13, the direction in which the linear portion 402 is led out of the recessed portion 22 is indicated by the arrow A2. In the second modified example, a first reentrant angle portion 224 is provided on the recessed portion 22, a first salient angle portion 324 corresponding to the first reentrant angle portion 224 is provided on the raised portion 32, a second reentrant angle portion 325 is provided on the raised portion 32, and a second salient angle portion 225 corresponding to the second reentrant angle portion 325 is provided on the recessed portion 22. When the linear portion 402 is pulled in the direction of the arrow A2 outside the holder 2, the linear portion 402 is pressed against the first salient angle portion 324 and the second salient angle portion 225 by the pulling force, and as a result, the contact surface pressure increases and transmission of the pulling force to the protruding portion 401 side is suppressed. The first salient angle portion 324 and the second salient angle portion 225 are formed at a substantially right angle by the intersection of the direction of the arrow A2 and a direction perpendicular to the direction of the arrow A2.

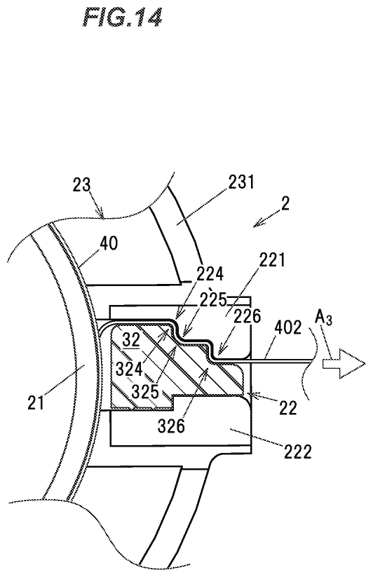

FIG. 14 is a configuration diagram illustrating the recessed portion 22 of the holder 2 and the raised portion 32 of the cover member 3 in the third modified example, which are shown together with a portion of the linear portion 402 of the flexible substrate 4. In FIG. 14, the direction in which the linear portion 402 is led out of the recessed portion 22 is indicated by the arrow A3. In the third modified example, in addition to the first reentrant angle portion 224, the first salient angle portion 324, the second reentrant angle portion 325 and the second salient angle portion 225, a third salient angle portion 226 is provided on the recessed portion 22 and a third reentrant angle portion 326 corresponding to the third salient angle portion 226 is provided on the raised portion 32. When the linear portion 402 is pulled in the direction of the arrow A3 outside the holder 2, the linear portion 402 is pressed against the first salient angle portion 324, the second salient angle portion 225 and the third salient angle portion 226 by the pulling force, and as a result, the contact surface pressure increases and transmission of the pulling force to the protruding portion 401 side is suppressed.

### Summary of the Embodiment

Technical ideas understood from the embodiment will be described below citing the reference signs, etc., used for the embodiment. However, each reference sign, etc., described below is not intended to limit the constituent elements in the claims to the members, etc., specifically described in the embodiment.

According to the first feature, a magnetostrictive torque sensor 1, which is attached around a rotating shaft 8 exhibiting a magnetostrictive effect and detects torque transmitted by the rotating shaft 8, comprises: a holder 2 being composed of a resin and comprising a cylinder portion 21 with a hollow cavity 20 in a center through which the rotating shaft 8 is inserted; and a flexible substrate 4 that comprises a detection portion 40 on which a coil group 4A to 4D comprising a combination of a plurality of detection coils 410 to 419, 420 to 429, 430 to 439, 440 to 449 aligned in a predetermined direction is formed by a wiring pattern, and a signal line portion 400 on which a plurality of signal lines 491 to 494 electrically connecting the coil group 4A to 4D to an external device 6 are formed by a wiring pattern, wherein the flexible substrate 4 is arranged in such a manner that the detection portion 40 is wrapped around an outer circumference of the cylinder portion 21 of the holder 2 and held by the holder 2, and a portion of the signal line portion 400 is led out of the holder 2.

According to the second feature, in the magnetostrictive torque sensor 1 as described by the first feature, the detection portion 40 has a rectangular shape with a long-side direction coincident with an alignment direction of the plurality of detection coils 410 to 419, 420 to 429, 430 to 439, 440 to 449, the signal line portion 400 comprises a protruding portion 401 protruding from the detection portion 40 in a direction perpendicular to the long-side direction, and a linear portion 402 extending from the protruding portion 401 in the long-side direction, and a portion of the linear portion 402 is led out of the holder 2.

According to the third feature, in the magnetostrictive torque sensor 1 as described by the second feature, the holder 2 comprises a recessed portion 22 to house the portion of the linear portion 402, and the linear portion 402 is bent inside the recessed portion 22 and is led out of the holder 2 so as to extend in a direction perpendicular to a circumferential direction of the cylinder portion 21.

According to the fourth feature, the magnetostrictive torque sensor 1 as described by the third feature further comprises: a cover member 3 comprising a raised portion 32 fitted into the recessed portion 22 of the holder 2, wherein the linear portion 402 is sandwiched and held between an inner surface (the facing surface 221b) of the recessed portion 22 and an outer peripheral surface 32a of the raised portion 32.

According to the fifth feature, in the magnetostrictive torque sensor 1 as described by the fourth feature, one of the recessed portion 22 and the raised portion 32 comprises a salient angle portion 225, 323, 324, 326 at which contact surface pressure between the salient angle portion 225, 323, 324, 326 and the linear portion 402 increases when the linear portion 402 is pulled outside the holder 2, the other of the recessed portion 22 and the raised portion 32 comprises a reentrant angle portion 223, 224, 226, 325 corresponding to the salient angle portion 225, 323, 324, 326, and the linear portion 402 is arranged between the salient angle portion 225, 323, 324, 326 and the reentrant angle portion 223, 224, 226, 325.

According to the sixth feature, the magnetostrictive torque sensor 1 as described by the fourth or fifth feature further comprises a magnetic ring 5 with a cylindrical shape comprising a soft magnetic material and being arranged so as to surround an outer circumference of the detection portion 40 of the flexible substrate 4, wherein movement of the cover member 3 in a direction in which the raised portion 32 separates away from the recessed portion 22 of the holder is restricted by the magnetic ring 5.

According to the seventh feature, in the magnetostrictive torque sensor 1 as described by the sixth feature, the detection portion 40 of the flexible substrate 4 is adhered to the cylinder portion 21 of the holder 2, and a space is formed between the detection portion 40 and the magnetic ring 5.

Although the embodiment and modified examples of the invention have been described, the invention according to claims is not to be limited to the embodiment and modified examples described above. Further, please note that not all combinations of the features described in the embodiment and modified examples are necessary to solve the problem of the invention.

1. A magnetostrictive torque sensor that is configured to be attached around a rotating shaft exhibiting a magnetostrictive effect and detects torque transmitted by the rotating shaft, the magnetostrictive torque sensor comprising:
a holder being composed of a resin and comprising a cylinder portion with a hollow cavity in a center through which the rotating shaft is inserted; and
a flexible substrate that comprises a detection portion on which a coil group comprising a combination of a plurality of detection coils aligned in a predetermined direction is formed by a wiring pattern, and a signal line portion on which a plurality of signal lines electrically connecting the coil group to an external device are formed by a wiring pattern,
wherein the flexible substrate is arranged in such a manner that the detection portion is wrapped around an outer circumference of the cylinder portion of the holder and held by the holder, and a portion of the signal line portion is led out of the holder.

2. The magnetostrictive torque sensor according to claim 1, wherein the detection portion has a rectangular shape with a long-side direction coincident with an alignment direction of the plurality of detection coils, wherein the signal line portion comprises a protruding portion protruding from the detection portion in a direction perpendicular to the long-side direction, and a linear portion extending from the protruding portion in the long-side direction, and wherein a portion of the linear portion is led out of the holder.

3. The magnetostrictive torque sensor according to claim 2, wherein the holder comprises a recessed portion to house the portion of the linear portion, and wherein the linear portion is bent inside the recessed portion and is led out of the holder so as to extend in a direction perpendicular to a circumferential direction of the cylinder portion.

4. The magnetostrictive torque sensor according to claim 3, further comprising:
a cover member comprising a raised portion fitted into the recessed portion of the holder,
wherein the linear portion is sandwiched and held between an inner surface of the recessed portion and an outer peripheral surface of the raised portion.

5. The magnetostrictive torque sensor according to claim 4, wherein one of the recessed portion and the raised portion comprises a salient angle portion at which contact surface pressure between the salient angle portion and the linear portion increases when the linear portion is pulled outside the holder, wherein an other of the recessed portion and the raised portion comprises a reentrant angle portion corresponding to the salient angle portion, and wherein the linear portion is arranged between the salient angle portion and the reentrant angle portion.

6. The magnetostrictive torque sensor according to claim 4, further comprising:
a magnetic ring with a cylindrical shape comprising a soft magnetic material and being arranged so as to surround an outer circumference of the detection portion of the flexible substrate,
wherein movement of the cover member in a direction in which the raised portion separates away from the recessed portion of the holder is restricted by the magnetic ring.

7. The magnetostrictive torque sensor according to claim 6, wherein the detection portion of the flexible substrate is adhered to the cylinder portion of the holder, and a space is formed between the detection portion and the magnetic ring.
